(19) United States
(12) Patent Application Publication
(10) Pub. No.: US 2002/0064958 A1
(43) Pub. Date: May 30, 2002

(54) Exposure method

(76) Inventor: Koichi Takeuchi, Mie (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/982,433

(22) Filed: Oct. 18, 2001

(30) Foreign Application Priority Data
Oct. 19, 2000 (JP) P2000-318901

(51) Int. Cl. H01L 21/311; H01L 21/302; H01L 21/461

(52) U.S. Cl. 438/695; 438/708

(57) ABSTRACT

The invention provides a pattern forming method in which a minute resist pattern can be formed with uniform dimension accuracy in the plane of a substrate, while manufacturing costs and processing time are not increased. In a pattern forming method in which after a first resist pattern containing a photo-acid generating agent is formed on a substrate by a lithography method, a resist film containing a cross-linking agent, which reacts with acid, is coated on the substrate in a state where it covers the first resist pattern, a crosslinking reaction is made to occur at an interface between the first resist pattern and the resist film to grow a cross-linked layer, and a second resist pattern made of the cross-linked layer and the first resist pattern is formed, a step of irradiating the first resist pattern with light is carried out before the resist film is coated on the substrate.

### BACKGROUND OF THE INVENTION

1. Field of the Invention

The present invention relates to a pattern forming method, and particularly to a pattern forming method for forming a minute resist pattern which becomes a processing mask in manufacture of a semiconductor device, a micro-machine, or the like.

2. Description of the Related Art

As the integration of semiconductor devices becomes high, minuteness of patterns of gates, wiring lines, connection holes or the like has been advanced. These patterns are formed by etching various under films to be processed while resist patterns formed by a lithography technique are used as masks. The lithography technique is constituted by respective steps of resist coating, pattern exposure, and development treatment, and a minimum line width R of a resist pattern formed by this is given by the following expression (1).

R=K1×λ/NA (1)

Where, in the expression (1), K1 is a constant caused by a process, λ is a wavelength of exposure light, and NA is a numerical aperture of a projection lens.

From such expression (1), it is understood that shortening of the exposure light wavelength λ and raising of the NA of the projection lens are effective in the improvement of minuteness (thinning of the minimum line width) of the resist pattern. Thus, in the pattern exposure in the lithography, the wavelength of exposure light has been shortened, such as a g line (wavelength 436 nm) of a mercury lump, an i line (wavelength 356 nm), a KrF excimer laser (wavelength 248 nm), and an ArF excimer laser (wavelength 193 nm). With this, the projection lens of the exposure apparatus having a high numerical aperture has been developed year by year.

Besides, in order to further improve the minuteness of the resist pattern, not only resolution but also increase of the focal depth of the exposure light becomes important. That is, a defocus margin corresponding to a step of a substrate, aberration of a lens, thickness of a resist, and focus variation of an exposure apparatus becomes necessary. The focal depth d is given by the following expression (2).

d=K2×λ/(NA)² (2)

Where, in the expression (2), K2 is a constant caused by a process, λ is a wavelength of exposure light, and NA is a numerical aperture of a projection lens.

From this expression (2), it is understood that shortening of the wavelength of the exposure light is also effective for the increase of the focal depth d. On the other hand, it is understood that in the case where the numerical aperture NA of the projection lens is raised to improve the resolution, the focal depth d is decreased.

Thus, in order to compensate the decrease of the focal depth d caused by raising the numerical aperture NA of the projection lens, it is necessary to increase the focal depth by other means. As one of the means, there is a method in which the resist is made a thin film, and the process constant K2 in the expression (2) is increased. Besides, thinning of the resist has also an effect of suppressing a pattern fall due to surface tension at the time of development.

However, in the case where the resist is made thin, there arises a fear that the thickness of a resist pattern at the time when a film to be processed as an under layer is etched becomes insufficient. Thus, the limit of thinning of the resist is determined by etching resistance of the resist material. Besides, in the case where the resist is made thin, variation in the amount of light absorption in the resist by interference between reflected light from the under layer and incident light, the so-called standing wave effect is increased. In order to suppress the influence of the reflected light from the under layer, an organic antireflection film or an antireflection film formed by a CVD (chemical vapor deposition) technique is generally provided as a lower layer of the resist. However, in the method in which the antireflection film is used to prevent the occurrence of the standing wave effect due to the thinning of the resist, since the antireflection film must also be etched, the resist must be made thick by that, and the limit of the thinning of the resist is also determined by this.

Then, as published by T. Azuma et al all, “Resist design for resolution limit of KrF imaging towards 130 nm lithography”, J. Vac. Sci. Technol., B16, 3734 (1998), or the like, there is a method in which a thin film, such as a silicon nitride film, a polysilicon film, or an amorphous silicon film, formed by a CVD technique on a film to be processed is formed as an intermediate film, and the film to be processed is etched through this. That is, the film to be processed is etched while a resist pattern is used as a mask, and further, the film to be processed is etched while this intermediate film is used as a mask. As the intermediate film, one having a high etching selection ratio to the film to be processed is used. According to this method, the thickness of the resist pattern has only to be such a thickness that it is needed to etch the intermediate film, and considerable thinning of a film can be achieved as compared with a case where there is no intermediate film.

In addition to this, Japanese Patent Laid-Open No. 73927/1998 discloses a method in which after a resist pattern containing a photo-acid generating agent is formed on a substrate, a resist film containing a cross-linking agent, which reacts with acid, is coated on the substrate in a state where it covers this resist pattern, and a cross-linking reaction is made to occur at an interface between the resist pattern and the resist so that a cross-linked layer grows. At this time, light is irradiated after the resist film is coated, so that acid is sufficiently generated in the resist pattern. According to such a method, since the cross-linked layer is formed in a state where it covers the resist pattern, the film thickness of the cross-linked layer is added to the resist pattern, and the thickness of the resist pattern formed by lithography can be made thin by the amount of addition.

However, the foregoing pattern forming methods have problems as follows:

That is, in the method of forming the intermediate film, it is necessary to carry out the film formation step, such as the CVD method, which requires a time of the film formation, and a washing step or the like by the provision of the intermediate film is added. Further, if the intermediate film remains, there is a case where electrical characteristics of a device are deteriorated, and it is necessary to carry out a step of removing the intermediate film after the film to be processed is etched. From the above, there is a problem that manufacturing costs and processing time are increased.

In the method of growing the cross-linked layer at the interface of the resist pattern, it is not necessary to carry out a film formation step such as the CVD method, and as compared with the method of providing the intermediate film, the increase in manufacturing cost and processing time can be suppressed. However, since light is irradiated to the resist pattern through the resist film containing the cross-linking agent, multiple interference of light occurs in the resist film, and it is impossible to uniformly irradiate the resist pattern with light on the whole surface of the substrate. Thus, fluctuation occurs in the amount of generation of the acid generated in the resist pattern, and it becomes difficult to make the film thickness of the cross-linked layer formed at the interface of the resist pattern uniform in the plane of the substrate. Accordingly, the dimension accuracy of a second resist pattern made of the cross-linked layer and the resist pattern fluctuates in the plane of the substrate, and the dimension accuracy of under layer processing using this second resist pattern as a mask can not be obtained.

Therefore, an object of the present invention is to provide a pattern forming method in which a minute resist pattern can be formed with uniform dimension accuracy in a plane of a substrate and without increasing manufacturing costs and processing time.

### SUMMARY OF THE INVENTION

A pattern forming method of the present invention to achieve the object is characterized by the following procedure. First, a first resist pattern containing a photo-acid generating agent is formed on a substrate, and light is irradiated to this first resist pattern. Thereafter, a resist film containing a cross-linking agent, which reacts with acid, is coated on the substrate in a state where it covers the first resist pattern, and a cross-linking reaction is made to occur at an interface of the first resist pattern to make a cross-linked layer grow, so that a second resist pattern made of the cross-linked layer and the first resist pattern is formed.

In such a pattern forming method, light is irradiated to the first resist pattern before the first resist pattern is covered with the resist film. Thus, the light irradiation to the first resist pattern is carried out in a state where multiple interference of light in the resist film is prevented, and the amount of effective light irradiation on the whole surface of the substrate is made uniform. Accordingly, on the whole surface of the substrate, a uniform amount of acid is generated in the first resist pattern, and the cross-linked layer with a uniform thickness can be formed at the exposed interface of the first resist pattern.

### BRIEF DESCRIPTION OF THE DRAWINGS

FIGS. 1A to 1E are sectional process views showing an embodiment of a pattern forming method of the present invention.

FIG. 2 is a structural view of a semiconductor manufacturing apparatus for carrying out a pattern forming method of the present invention.

FIG. 3 is a structural view of a light irradiation unit used for the semiconductor manufacturing apparatus of FIG. 2.

FIGS. 4A to 4D are sectional structural views (No. 1) showing an example in which the present invention is applied to a manufacturing method of a semiconductor device.

FIGS. 5A to 5E are sectional structural views (No. 2) showing the example in which the present invention is applied to the manufacturing method of the semiconductor device.

FIG. 6 is a sectional view for explaining a comparative example in relation to the example.

### DETAILED DESCRIPTION OF THE PREFERRED EMBODIMENTS

Hereinafter, a pattern forming method of the present invention will be described in detail with reference to the drawings. Here, a description will be given of an embodiment in which the pattern forming method of the present invention is applied to a manufacturing process of a semiconductor device. Incidentally, the pattern forming method of the present invention is not limited to the application to the manufacturing process of the semiconductor device, but can be widely applied to a manufacturing process of a micromachine or other manufacturing processes requiring the processing of minute patterns.

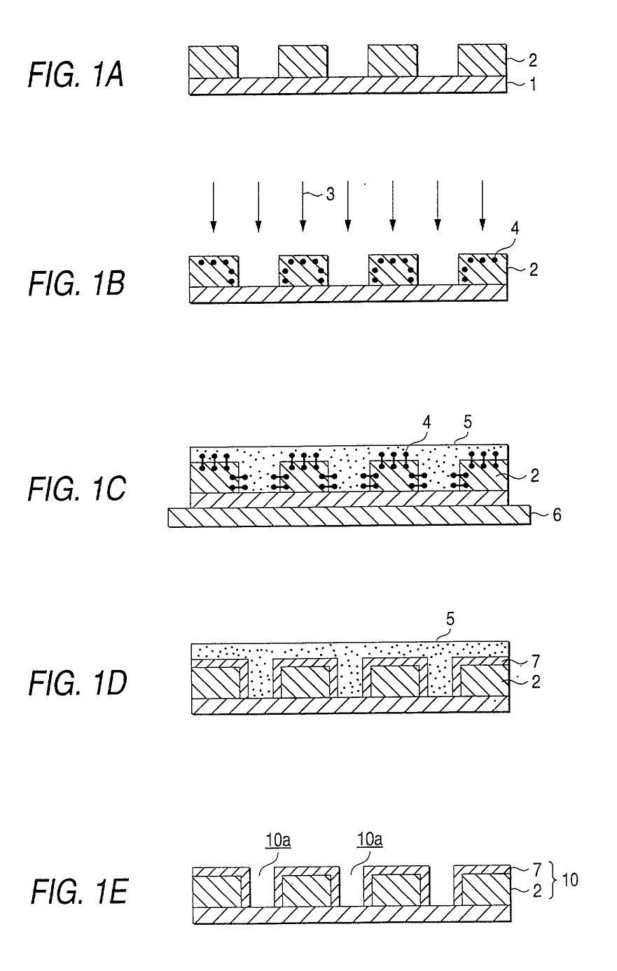

First, as shown in FIG. 1A, a first resist pattern 2 is formed by a lithography method on a substrate 1 made of a semiconductor wafer. Here, lithography using a chemical amplification resist is carried out. The chemical amplification resist is a resist containing a photo-acid generating agent, and a pattern is formed by using a catalytic reaction of acid generated by pattern exposure in the lithography.

Besides, in the pattern exposure in this lithography, according to the line width of the first resist pattern 2 and the pattern interval, and a resist material to be used, the exposure is carried out by using an exposure apparatus suitably selected from a KrF excimer laser exposure apparatus, an i line exposure apparatus, an ArF excimer laser exposure apparatus, an F₂ laser exposure apparatus, an electron beam drawing apparatus, an X-ray drawing apparatus, an X-ray exposure apparatus and the like.

At this time, the resist material in accordance with the exposure means is suitably selected and is used. For example, in the case where the I line of mercury is used as the exposure light, a novolac resin is used as a base resin of the resist material. In the case where the light of the ArF excimer laser light (wavelength 193 nm) is used as the exposure light, a methacrylic resin or cycloolefin resin is used as a base resin. The photo-acid generating agent in the resist material is not particularly limited, and sulfonium salt, urea or the like is used.

Next, as shown in FIG. 1B, second exposure is carried out in which the first resist pattern 2 is irradiated with light 3. At this time, the light 3 is uniformly irradiated to the whole surface of the substrate 1, and an acid 4 is sufficiently generated in the inside of the second resist pattern 2. In order to carry out such exposure, it is desirable to use an exposure unit as described later, which can irradiate the whole surface of the substrate 1 with the light 3 at the same time. Besides, the wavelength of the light 3 is not particularly limited as long as it is absorbed by the photo-acid generating agent in the first resist pattern 2.

Thereafter, as shown in FIG. 1C, a resist film 5 containing a cross-linking agent, which reacts with acid, is coated and formed on the substrate 1 in a state where it covers the resist pattern 2. At this time, a non-hardened resist material containing the cross-linking agent is spin coated on the substrate 1.

The resist material used here is a mixture of a base resin made of, for example, polyvinyl alcohol system, polyacrylic acid system, polyvinyl acetal system or the like, a soluble cross-linking agent of urea system, melamine system or the like, water as a solvent, a soluble solvent for improving a coating property, and an additive such as a surfactant.

Next, for example, the substrate 1 is put on a hot plate 6 and is heated, so that the acid 4 in the first resist pattern 2 is diffused into the resist film 5. By this, as shown in FIG. 1D, in the vicinity of the interface of the first resist pattern 2, the cross-linking agent in the resist film 5 and the acid 4 are made to react with each other, and a cross-linked layer 7 is formed at the interface of the first resist pattern 2. The thickness of the cross-linked layer 7 to be grown is controlled by optimizing the heating temperature and heating time of the substrate 1. At this time, although the increase in the cross-linked layer 7 becomes large as the heating temperature becomes high, the heating temperature is set within a temperature range lower than softening start temperature of the first resist pattern 2.

Next, as shown in FIG. 1E, after the substrate 1 is returned to the room temperature, the resist film 5 of an unreacted portion is washed off by using a rinse solution. By this, a second resist pattern 10 made of the first resist pattern 2 and the cross-linked layer 7 covering this is obtained. The second resist pattern 10 has the thickness of the sum of the thickness of the first resist pattern 2 formed by the lithography and the thickness of the cross-linked layer 7.

In the above method, before the first resist pattern 2 is covered with the resist film 5, the light 3 is irradiated to the first resist pattern 2. Thus, the light irradiation in which the multiple interference of the light 3 in the resist film 5 is prevented, can be carried out to the first resist pattern 2 on the substrate 1, and the amount of effective light irradiation on the whole surface of the substrate 1 is uniformed. Accordingly, on the whole surface of the substrate 1, a uniform amount of acid can be generated in the first resist pattern 2, and it becomes possible to grow the cross-linked layer 7 of a sufficient thickness uniformly at the interface of the first resist pattern 2 on the whole surface of the substrate 1. As a result, it becomes possible to form the second resist pattern 10 having the uniform thickness and dimension accuracy on the substrate 1.

Further, since this second resist pattern 10 has the thickness of the first resist pattern 2 added with the thickness of the cross-linked layer 7, the thickness of the first resist pattern 2 can be made thin by the addition. Accordingly, in the lithography in the case where the first resist pattern 2 is formed, it becomes possible to carry out the pattern exposure with higher resolution. As a result, without forming an intermediate film by a CVD method or the like, that is, without increasing the manufacture costs and manufacture time, it becomes possible to form the resist pattern 2 having a minuter line width and opening width.

Particularly, in this case, since the cross-linked layer 7 is formed also on the side wall of the first resist pattern 2, the line width of the remaining pattern of the second resist pattern 10 is expanded. Accordingly, in the case where an object is to accelerate the improvement in minuteness, it is desirable that the application is made to a case where an object is to form a removed pattern 10a such as a hole pattern or a groove pattern. In the second exposure where the light 3 is irradiated to the first resist pattern 2, as compared with the side wall of the first resist pattern 2, the light 3 is more irradiated to its upper surface. Thus, the thickness of the cross-linked layer 7 at the side of the upper surface becomes thicker than that at the side of the side wall of the first resist pattern 2 .

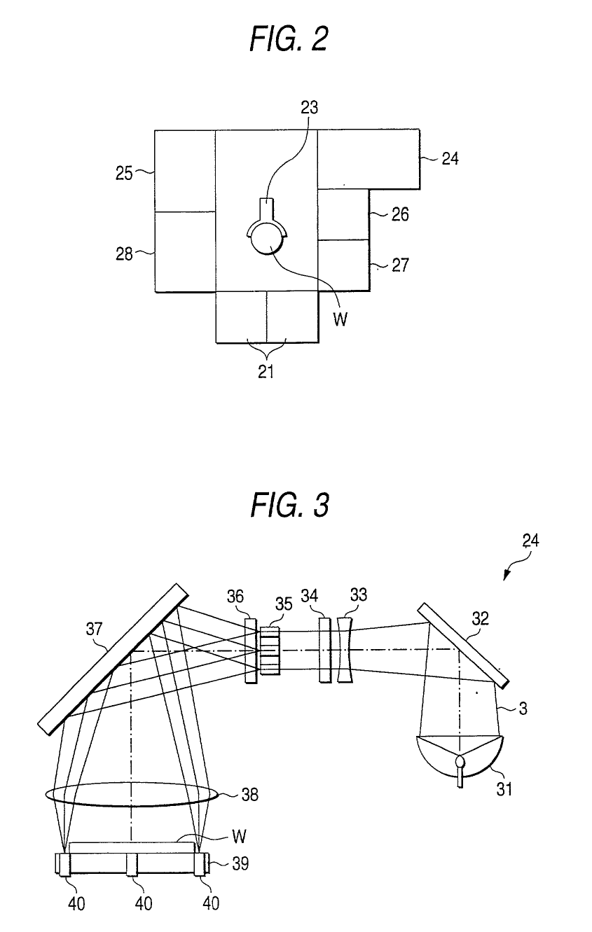

Next, a manufacturing apparatus for carrying out a pattern forming method like this will be described as a structure of a semiconductor manufacturing apparatus. FIG. 2 is a structural view showing an example of the semiconductor manufacturing apparatus. The semiconductor manufacturing apparatus shown in this drawing includes carrier box arrangement portions 21, 21 in which a carrier box (not shown) containing a wafer W (that is, a substrate) to be processed is placed, and a wafer transfer part 23 provided adjacently to the carrier box arrangement portions 21.

Moreover, the following respective units are arranged in a state where they surround the wafer transfer part 23. There are provided a light irradiation unit 24 for irradiating the wafer W with light, a spin coating unit 25 for coating the wafer W with a resist film, a heating unit 26 for heating the wafer W coated with the resist film, a wafer drying and cooling unit 27 for drying and cooling the heated wafer W, and a wafer washing unit 28 for removing the resist film on the surface of the wafer w.

Then, the wafer contained in the carrier box of the carrier box arrangement portion 21 is transferred to the respective units by the wafer transfer part 23 and is subjected to a treatment in each of the units.

Among these units, the light irradiation unit 24 for irradiating the wafer W with light is constructed, for example, as shown in FIG. 3. The light irradiation unit shown in this drawing includes a light source 31 made of, for example, a high pressure mercury lamp, and a mirror 32, a concave lens 33, a shutter 34, a fly-eye lens 35, a slit 36, a mirror 37, a convex lens 38, a stage 39, and an illumination meter 40 are successively arranged in a passage of light 3 irradiated from the light source 31.

The light 3 irradiated from the light source 31 is reflected by the mirror 32, passes through the shutter 34, and is incident on the fly-eye lens 35. This fly-eye lens 35 is made of a plurality of bundled small convex lenses, has limited directivity and uniform diffusion characteristics, and averages and uniformly diffuses the incident light 3. This fly-eye lens 35 becomes a secondary light source, and the light passes through the slit 36. This slit 36 is for shading the periphery of a light flux in order to prevent light from being scattered at the periphery of the lens. The light 3 having passed through the slit 36 passes through the convex lens 38 and becomes a parallel light 3, and is uniformly irradiated to the whole surface of the wafer W placed on the stage 39. The amount of irradiation of the light 3 is controlled by an opening time of the shutter 34, and the illumination is corrected by the illumination meter 40 in advance.

As the spin coating unit 25, a resist spin coating unit of a coater developer is used. This spin coating unit 25 includes a rotary wafer chuck and an agent supply nozzle, and a resist material solution containing a cross-linking agent is supplied from the agent supply nozzle onto the wafer W rotatively held by the rotary wafer chuck, and by this, a resist film is spin coated on the surface of the wafer W.

The heating unit 26 includes a block for evaporating a solvent (for example, water) of the resist film coated on the wafer W, and a block for heating the wafer W to form the cross-linked layer, and the respective blocks are arranged vertically in two stages. Each of the blocks includes a heating plate and is constructed such that the temperature of the heating plate can be controlled with accuracy of ±0.5° C. in the plane of the wafer W. Further, in order to make the temperature distribution in the plane of the wafer W uniform, there is provided an exhaust port for adjusting an air flow around the wafer W.

Then, the wafer drying and cooling unit 27 is constituted by a block including a heating plate for drying the wafer W and a block including a cooling plate for cooling the wafer W to the room temperature, and the respective blocks are arranged vertically in two stages.

A development unit of a coater developer is used as the wafer washing unit 28. A rotary wafer chuck and two agent supply nozzles are provided in the wafer washing unit 28, and to the wafer W rotatively held by the rotary wafer chuck, isopropyl alcohol is supplied from the one agent supply nozzle, and pure water is supplied from the other agent supply nozzle. By this, the surface of the wafer W can be treated by isopropyl alcohol and pure water, and rotation drying of the wafer W can be carried out.

By using the semiconductor manufacturing apparatus of such structure, it becomes possible to carry out the respective steps explained by use of FIG. 1 continuously and in line.

Besides, since the light irradiation unit 24 for uniformly irradiating the whole surface of the wafer W with light is provided, the amount of effective light irradiation on the whole surface of the wafer W (substrate 1) can be made further uniform, and it becomes possible to uniformly grow the cross-linked layer 7 having a sufficient thickness at the interface of the resist pattern 2 on the whole surface of the substrate 1.

Incidentally, the semiconductor manufacturing apparatus of such structure can also be obtained by altering, for example, a general coater developer. The coater developer includes a carrier box arrangement portion, a wafer transfer part, a peripheral exposure irradiation unit, a spin coating unit, a development unit, a heating unit, and a wafer drying and cooling unit. Here, the peripheral exposure unit irradiates a wafer edge with exposure light to remove a resist (positive type) of the wafer edge at the time of development. Thus, the peripheral exposure unit is altered into the foregoing light irradiation unit 24, a resist material solution containing a cross-linking agent is made to be supplied from an agent supply nozzle of the spin coating unit, and isopropyl alcohol is made to be supplied from an agent supply nozzle of the development unit, so that it is enabled to be used as the semiconductor manufacturing apparatus of the foregoing structure.

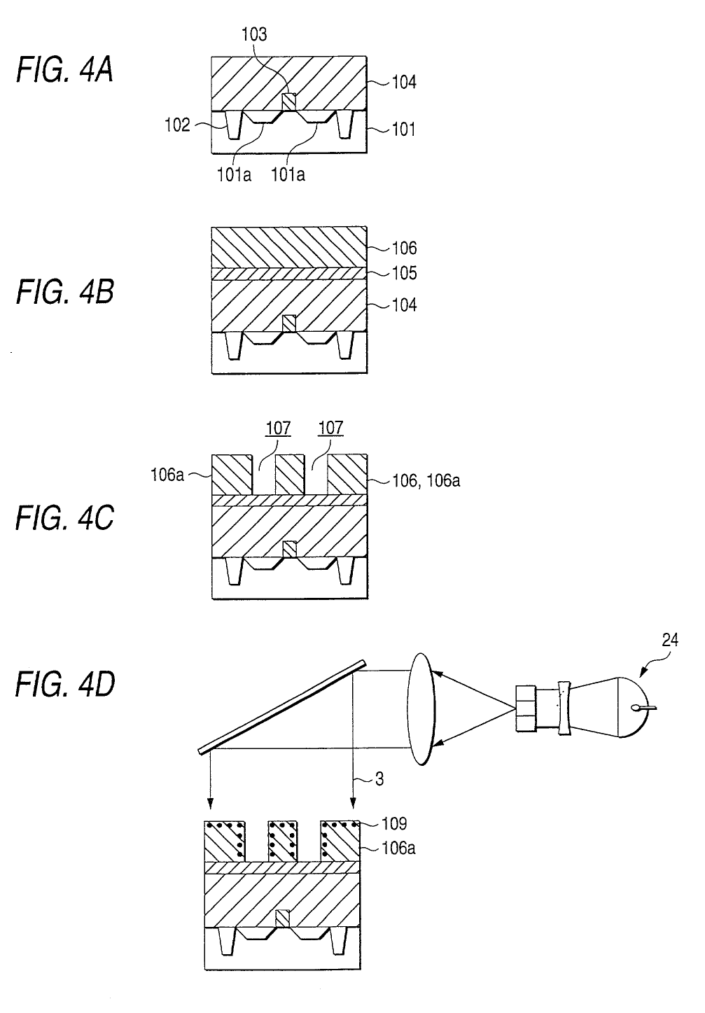

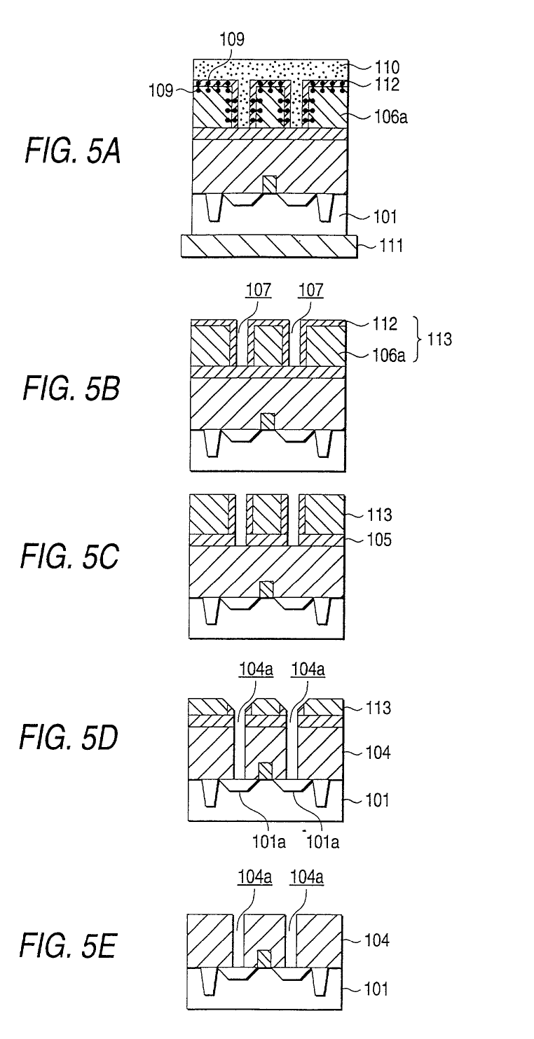

Next, a specific example in which the pattern forming method of the present invention is applied to a manufacturing process of a semiconductor device will be described by use of FIG. 4 and FIG. 5.

First, as shown in FIG. 4A, an element separation 102 was formed at a surface side of a silicon substrate 101, and next, a gate electrode 103 having a line width of 0.1 μm was formed on the silicon substrate 101, and source/drain diffusion layers 101a were formed on the surface layer of the silicon substrate 101. Next, after a silicon oxide film 104 which became an interlayer insulating film was formed on the silicon substrate 101 by a CVD method, the surface of the silicon oxide film 104 was flattened by a CMP (Chemical Mechanical Polishing) method. By this, the thickness of the silicon oxide film 104 was made 500±50 nm. At this time, the thickness of the silicon oxide film 104 had fluctuation within a range of ±50 nm due to fluctuation of a shaving amount at the CMP step.

Next, as shown in FIG. 4B, an antireflection film 105 made of an organic material and having a thickness of 135 nm was spin coated on the silicon oxide film 104. At this time, the thickness of the antireflection film 105 was made as thick as 135 nm in order to sufficiently suppress the reflected light from an under layer in pattern exposure at a next step. In the case where the thickness of the antireflection film 105 is not sufficient, the state of interference of light is changed by the fluctuation in the thickness of the silicon oxide film 104, and the intensity of the reflected light from the under layer is changed by that. Thus, in the formation of a resist pattern by the pattern exposure and development at the next step, its size fluctuates.

Next, a positive type chemical amplification resist 106 having a thickness of 390 nm was spin coated on the antireflection film 105. As the chemical amplification resist 106, one mainly containing a photo-acid generating agent of sulfonium salt, and polyhydroxy stainless resin having an acetal group as a protecting group, which was a resist for KrF excimer laser lithography, was used.

Next, exposure of a hole pattern to the chemical amplification resist 106 was carried out by using a KrF excimer laser scanner (exposure wavelength 248 nm) with a projection lens of a reduction rate of ¼, and after the substrate 101 was heated for 90 seconds at 1300° C., it was developed by using a diluted solution of 2.0 wt. % of TMAH (tetramethylammonium hydroxide), and was finally washed by pure water. By this, as shown in FIG. 4C, a first resist pattern 106a having a hole pattern 107 of a diameter of 220 nm was formed.

Next, as shown in FIG. 4D, light 3 was uniformly irradiated to the substrate 101 at the total exposure amount of 80 J/m² by a mercury lamp 108, and an acid 109 was generated by this in the surface layer of the first resist pattern 106a. At this time, a light irradiation unit 24 having the structure explained by use of FIG. 3 was used.

Next, as shown in FIG. 5A, a resist film 110 containing a cross-linking agent and having a thickness of 800 nm was spin coated on the substrate 101. At this time, a resist material solution to be coated is made of a soluble resin of polyvinyl alcohol system, a cross-linking agent of urea system, water as a solvent, and an additive such as a surfactant. Thereafter, the substrate 101 was placed on a heating plate 111 and was heated. At this time, first, heating at 850° C. for 70 seconds was carried out to evaporate the solvent in the solution. Next, heating at 110° C. for 70 seconds was carried out, and the acid on the surface of the first resist pattern 106a was diffused into the resist film 110. By this, the acid 109 diffused in the resist film 110 and the cross-linking agent in the resist film 110 were made to react with each other, and a cross-linked layer 112 insoluble in water was formed in a state where it covered the first resist pattern 106a.

Next, as shown in FIG. 5B, an isopropyl alcohol solution was poured onto the substrate 101, and the resist film (110) of a portion which was not cross-linked was dissolved and was removed. Finally, the substrate 101 was washed by pure water, and the substrate 101 was heated and was dried. By this, a second resist pattern 113 in which the surface of the resist pattern 106a was covered with the cross-linked layer 112 was formed. The height of the second resist pattern 113 became a thickness of 110 nm of the cross-linked layer 112+a height of 390 nm of the resist pattern 106a=500 nm, and the diameter of the hole pattern 107 was reduced from 220 nm to 100 nm.

Next, as shown in FIG. 5C, the antireflection film 105 of the lower layer was etched while the second resist pattern 113 was used as a mask. Etching conditions are as follows:

<Etching Conditions of the Antireflection Film 105>

Etching apparatus: inductive coupled plasma etcher

Kind of gas and quantity of flow: oxygen O₂ (10 sccm)/helium He (100 sccm)

Selection ratio of the second resist pattern 113 to the antireflection film 105: 1

Overetching amount: 30%.

Thereafter, as shown in FIG. 5D, the silicon oxide film 104 was further etched while the second resist pattern 113 was used as a mask. Etching conditions at this time are as follows:

<Etching Conditions of the Silicon Oxide Film 104>

Etching apparatus: parallel flat plate type plasma etcher

Kind of gas and quantity of flow: cyclobutane octafluoride C4F8 (2 sccm)/O₂ (10 sccm)/argon Ar (300 sccm)

Selection ratio of the second resist pattern 113 to the silicon oxide film 104: 3

Overetching amount: 30%

Where, the unit of the gas flow rate “sccm” stands for standard cubic centimeter/minutes, and indicates the flow speed of gas in a standard state.

In the manner as described above, a connection hole 104a reaching the diffusion layer 101a of the surface layer of the substrate 101 was formed in the silicon oxide film 104.

Thereafter, as shown in FIG. 5E, oxygen ashing was carried out from above the silicon oxide film 104 to remove the second resist pattern (113) remaining on the silicon substrate 101 and the organic antireflection film (105), and a post-treatment was carried out by a mixture solution of sulfuric acid and hydrogen peroxide.

By the above series of steps, the connection hole 104a of a diameter of 100 nm was formed in the silicon oxide film 104 of the upper portion of the substrate 101 with uniform dimension accuracy in the plane of the substrate 101.

Incidentally, the thickness of the second resist pattern 113 required for the formation of the connection hole 104a was set in the manner described below. First, the shaving thickness of the second resist pattern 113 by etching carried out twice was calculated.

The shaving thickness of the second resist pattern 113=(thickness of antireflection film/etching selection ratio)×(1+overetching amount)+(thickness of interlayer film/etching selection ratio)×(1+overetching amount)=(135 nm/1)×(1+0.3)+(500 nm/3)×(1+0.3)=175.5 nm+216.7 nm=392 nm.

Here, although the antireflection film 105 also functions as an etching mask, if a film decrease by etching reaches the antireflection film 105, the uniformity of the diameter of the connection hole 104a after etching is extremely deteriorated. Besides, since the opening portion of the hole pattern 107 of the second resist pattern 113 is expanded at the time of etching, also in order to prevent the expansion from reaching the lower portion of the hole pattern 107, it is necessary that the remaining film of the second resist pattern 113 after etching is at least 60 nm. Thus, the required thickness of the second resist pattern 113 becomes 392 nm+60 nm≅450 nm.

Then, in the above embodiment, the thickness of the second resist pattern 113 was made 500 nm. By this, the uniformity of the diameter and the shape of the connection hole 104a was ensured.

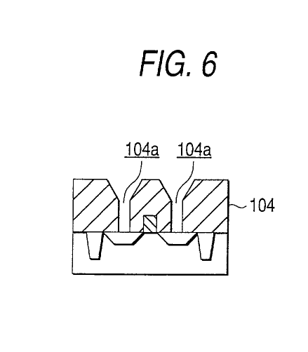

Incidentally, in the case where the connection hole is formed in the silicon oxide film 104 by using only the first resist pattern 106a as a mask while the cross-linked layer 112 is not formed, as shown in FIG. 6, an upper opening of the connection hole 104a in the silicon oxide film 104 is expanded. In such a case, electrical short-circuiting occurs between wiring lines formed on a portion between the connection holes 104a and on upper portions thereof, and a semiconductor device can not be fabricated.

As described above, according to the pattern forming method of the present invention, light is irradiated to the first resist pattern before the first resist pattern is covered with the resist film containing the cross-linking agent which reacts with acid, so that the second resist pattern with the uniform thickness and dimension accuracy can be formed in the plane of the substrate. Further, since it is not necessary to carry out film formation of an intermediate film by a CVD method or the like which takes a process time, it becomes possible to form the minuter second resist pattern with the uniform dimension accuracy in the plane of the substrate while the increase in manufacturing cost and manufacturing time is suppressed. As a result, it becomes possible to improve the shape accuracy of minute pattern processing using the second resist pattern as a mask in the plane of the substrate.

What is claimed is:

1. A pattern forming method, comprising the steps of:
forming a first resist pattern containing a photo-acid generating agent on a substrate;
irradiating light to an exposed surface of the first resist pattern;
coating a resist film containing a cross-linking agent, which reacts with acid, on the substrate after irradiation of the light in a state where it covers the first resist pattern;
causing a cross-linking reaction at an interface between the first resist pattern and the resist film to grow a cross-linked layer; and
forming a second resist pattern made of the cross-linked layer and the first resist pattern.

2. A pattern forming method according to claim 1, wherein the light is one selected from the group consisting of ArF excimer laser light and KrF excimer laser light.

3. A pattern forming method according to claim 1, wherein a base resin of a resist material forming the first resist pattern containing the photo-acid generating agent is one selected from the group consisting of methacrylic resin and cycloolefin resin.

4. A pattern forming method according to claim 1, wherein a base resin of the resist film containing the cross-linking agent, which reacts with the acid, is one selected from the group consisting of polyvinyl alcohol system resin, polyacrylic acid system resin, and polyvinyl acetal system resin.
